(19) United States
(12) Patent Application Publication
(10) Pub. No.: US 2010/0045306 A1
(43) Pub. Date: Feb. 25, 2010

(54) Microwave resonator and microwave microscope including the same

(76) Inventor: Norio Ookubo, Chiba-shi (JP)

Correspondence Address: BRUCE L. ADAMS, ESQ, ADAMS & WILKS, 17 BATTERY PLACE - SUITE 1231, NEW YORK, NY, 10004, US

(21) Appl. No.: 12/583,264

(22) Filed: Aug. 18, 2009

(30) Foreign Application Priority Data
Aug. 22, 2008 (JP) 2008-213750

(51) Int. Cl. G01R 27/04

(52) U.S. Cl. 324/637

(57) ABSTRACT

Provided is a microwave resonator of a both-end-opened type including: a first end and a second end; a conductor line; a ground conductor; and a measurement unit for measuring an amount associated with a complex dielectric constant of a sample while the measurement unit is brought close to the sample, in which the measurement unit is connected to the conductor line in a central portion joining the first end and the second end of the microwave resonator, and protrudes to an outside of the microwave resonator at a state estranged from the ground conductor.

### BACKGROUND OF THE INVENTION

1. Field of the Invention

The present invention relates to a microwave resonator for measuring electrical characteristics of an object at fine scales and performing imaging, and a microwave microscope including the microscope resonator. In particular, the present invention relates to a microwave resonator used in a microwave band and a microwave microscope including the microscope resonator.

2. Description of the Related Art

For measuring electrical characteristics of an object at fine length scales using an electrical resonator provided with a probe in a frequency band from several GHz to 20 GHz and performing imaging, there have been known, for example, a scanning capacitance microscope (SCM), a scanning nonlinear dielectric microscope (SNDM), and a scanning microwave microscope (SMM). In each of the microscopes, the probe is provided at one end of the electrical resonator and interference between the probe and a sample is measured as a change in an amount associated with resonant characteristics (resonant frequency and Q value). In this case, an excellent S/N ratio may be expected in the vicinity of the resonant frequency through the electrical resonator.

There have been known a technique using a series resonator (n>>1) which operates at a wavelength of nλ/4 (U.S. Pat. No. 5,900,618) and a technique using a magnetically coupled n/λ/4 resonator (US 2006/0087305). A technique using a parallel resonator to measure a response by a vector network analyzer (VAN) has also been known (US 2006/103583). In addition, a technique using an nλ/4 series coaxial resonator (n>>1) to control a distance between a probe and a sample by the STM has been known (JP-T 2003-509696 A).

Further, there have been known a technique capable of connecting a probe to an open end of a coaxial cable through a micro-strip line and attaching and detaching the probe to and from the coaxial cable using a connector (JP2001-305039A), and a technique for controlling a distance between a sample and a probe to a constant value based on a distance dependence of a response in a case where a capacitance response is modulated at a changed distance between the sample and the probe (JP 2002-168801 A).

There have been known a probe structure using a coaxial cable and a coplanar line (JP 2006-010678 A) and a technique for connecting a coaxial cable and a probe through a micro-strip (JP 05-527823 A).

In the SCM, the probe is provided at one end of a micro-strip line resonator which is a distributed constant circuit, and two devices for excitation and reception are magnetically coupled to an electrically closed end of the resonator. An excitation frequency is detuned from a resonant frequency of the resonator as appropriate. An amount associated with a capacitance of a sample is detected as a change in amplitude of a received signal at the excitation frequency, and imaged.

In the SNDM, a lumped constant circuit having a reactor and a capacitor is coupled to a capacitor under the probe to form a tank, and an amplifier circuit is added to the tank to construct an oscillator. A capacitance under the probe is detected as a change in oscillation frequency of the oscillator, that is, a change in resonant frequency of the tank, and imaged.

Two types of SMMs have been known in view of a resonator structure. In one of the types, a coaxial resonator whose one end is opened is used. The probe is provided at the opened end. The other end of the coaxial resonator is closed by a coaxial ground conductor. Two loops (excitation loop and reception loop) are magnetically coupled to a conductor line in the vicinity of the other end of the coaxial resonator. In the other type, a coaxial resonator whose both ends are opened is used. The probe is provided at one of the ends. A directional coupler for excitation and reception is capacitively coupled to the coaxial resonator at the other end. In both types, when a resonant frequency of the resonator is detected, an amount associated with a capacitance under the probe may be obtained.

An amount associated with an amplitude of a reflection output may be detected from the resonator to obtain an amount associated with a loss under the probe. In the former type, the detection is performed from the reception loop. In the latter type, the detection is performed by the directional coupler. There is also a method of constructing a resonator using a micro-strip line instead of the coaxial structure.

According to the SCM, a signal in which the capacitance and the electrical loss under the probe are mixed is detected, and hence the SCN has poor precision. In contrast to this, according to the SNDM, only the resonant frequency proportional to the capacitance is detected, and hence the SNDM has excellent precision. However, there is a drawback that the loss under the probe cannot be measured. The SCM and the SNDM have an advantage that a distance between the probe and the sample may be controlled to a constant value by, for example, an atomic force microscope (AFM). However, an applicable frequency is limited to a single frequency, and hence the SCM and the SNDM are not suitable for measurement in which electrical characteristics of the sample depend on a microwave frequency.

The SMM has an advantage that the capacitance and the loss under the probe, which are associated with a complex dielectric constant, may be detected at a plurality of microwave frequencies. However, there is a problem that it is difficult to control the distance between the probe and the sample. The conventional SMM also has a problem that an excited electromagnetic field is leaked to a received signal to reduce an S/N ratio because the excitation and the reception of output of the resonator are performed at the one end of the resonator. In addition, when the directional coupler for excitation and reception is capacitively coupled to the resonator, a microwave band in which the directional coupler may be used is limited, and hence there is a drawback that a microwave band that may be measured is limited.

### SUMMARY OF THE INVENTION

The present invention has been made in order to solve the problems described above. An object of the present invention is to provide a microwave resonator in which an S/N ratio is increased to improve measurement precision and measurement may be realized in a wide microwave band, and a microwave microscope including the microscope resonator.

In order to achieve the above-mentioned object, the present invention provides a microwave resonator of a both-end-opened type, comprising: a first end and a second end; a conductor line; a ground conductor; and measurement means for measuring an amount associated with a complex dielectric constant of a sample while the measurement means is brought close to the sample, wherein the measurement means is connected to the conductor line in a central portion joining the first end and the second end of the microwave resonator, and protrudes to an outside of the microwave resonator at a state estranged from the ground conductor.

With this structure, both the ends of the microwave resonator are opened. Therefore, when an excitation unit and a detection unit are capacitively coupled to the ends, the excitation unit for exciting the microwave resonator and the detection unit for detecting a microwave are separately provided at the ends of the microwave resonator, and hence the ends may be located at a sufficient distance so as not to interfere with each other.

The measurement unit is connected to the central portion of the conductor line joining the ends of the microwave resonator and made to protrude to the outside of the microwave resonator, and hence the measurement unit itself is provided at a large distance from the excitation unit and the detection unit.

As a result, a degradation of S/N ratio due to leakage or interference of the excited wave to or with the received (detection) signal and a degradation of S/N ratio due to interference between the measurement unit and each of the excitation unit and the detection unit are suppressed. Therefore, the complex dielectric characteristic of the sample may be measured while a high S/N ratio is maintained.

When a directional coupler which has a problem with band limitation or leakage is not used as the detection unit for the resonant state, a signal may be detected in a wide band at high sensitivity.

The microwave resonator may comprise one of a coaxial cable, a micro-strip line, a strip line, and a coplanar line.

The conductor line may be covered with the dielectric layer except the both ends. With this structure, little noise leaks at a time of measurement, and measurement precision is improved.

The measurement means may be provided in a cut out part of at least one of the ground conductor and the dielectric layer. With this structure, the measurement unit is exposed from the cut out portion. Therefore, the measurement unit may be easily brought close to the sample. A space for using various control units (including optical lever) for controlling the distance between the measurement unit and the sample is secured, and hence the distance control can be performed.

The measurement means may comprise one of a conductor having a sharp tip end and a coil.

The coil may comprise a coil frame containing carbon as a main component, and a conductive film coating a surface of the coil frame.

A microwave microscope according to the present invention comprises: the microwave resonator described above; excitation means which is capacitively coupled to one of the first end and the second end of the microwave resonator, for exciting the microwave resonator; and detection means which is capacitively coupled to another one of the first end and the second end of the microwave resonator, for detecting a microwave traveling from the another one of the first end and the second end.

The microwave microscope according to the present invention may further comprise distance control means for controlling a relative distance between the measurement means and the sample close to the measurement means.

With this structure, the distance between the measurement unit and the sample may be held to a substantially constant value, and hence reduction in measurement precision of a complex dielectric characteristic due to a change in distance between the measurement unit and the sample may be suppressed.

According to the present invention, the S/N ratio is increased to improve measurement precision and measurement may be realized in a wide microwave band.

### BRIEF DESCRIPTION OF THE DRAWINGS

In the accompanying drawings:

FIG. 1 is a block diagram illustrating the entire structure of a microwave microscope according to a first embodiment of the present invention;

FIG. 2 illustrates a detailed structure of a microwave resonator according to the first embodiment of the present invention;

FIG. 3 is a cross sectional view illustrating a strip line;

FIG. 4 is a partially enlarged view of FIG. 2, illustrating capacitive coupling;

FIG. 5 illustrates a structure of a microwave resonator according to a second embodiment of the present invention;

FIG. 6 is a partially enlarged view of FIG. 5, illustrating a cut out portion and a probe;

FIG. 7 is a partially enlarged view of FIG. 5, illustrating capacitive coupling;

FIG. 8 illustrates a structure of a microwave resonator according to a third embodiment of the present invention;

FIG. 9 is a partially enlarged view of FIG. 8, illustrating a cut out portion and a coil;

FIG. 10 illustrates a structure of a microwave resonator according to a fourth embodiment of the present invention;

FIG. 11 illustrates a structure of a microwave resonator according to a fifth embodiment of the present invention;

FIG. 12 illustrates a structure of a microwave resonator according to a sixth embodiment of the present invention; and

FIG. 13 illustrates a structure of a microwave resonator according to a seventh embodiment of the present invention.

### DETAILED DESCRIPTION OF THE PREFERRED EMBODIMENTS

Hereinafter, embodiments of the present invention is described with reference to the attached drawings.

### First Embodiment

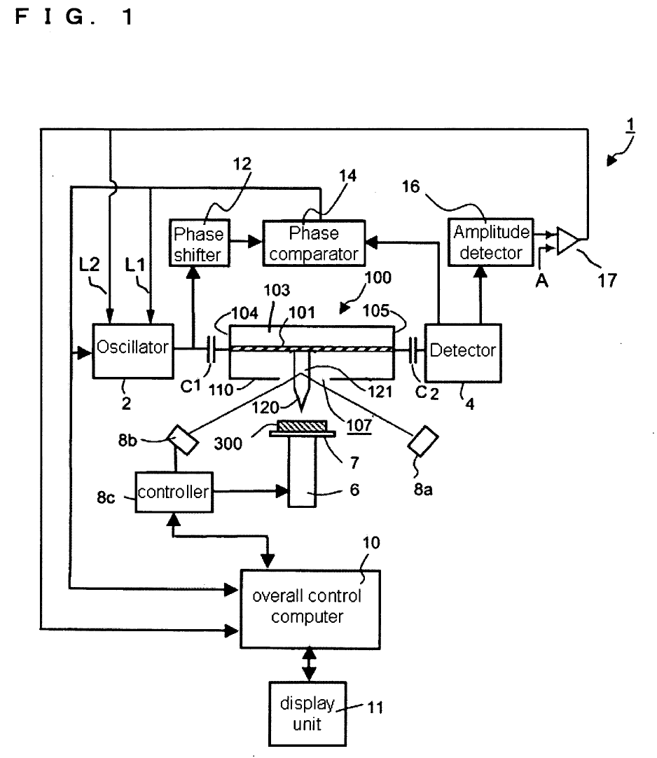

FIG. 1 is a block diagram illustrating the entire structure of a microwave microscope 1 according to a first embodiment of the present invention. In FIG. 1, the microwave microscope 1 includes a microwave resonator 100, an oscillator (excitation unit) 2 capacitively coupled to a first end 104 of the microwave resonator 100 (capacitive coupling expressed by reference symbol C1), a detector (detection unit) 4 capacitively coupled to a second end 105 of the microwave resonator 100 (capacitive coupling expressed by reference symbol C2), a piezoelectric actuator 6 scanning a relative position to microwave resonator 100 of a sample 300, and an overall control computer 10 for controlling an operation of the microwave microscope 1.

The microwave microscope 1 further includes a feedback control unit (phase shifter 12 and phase comparator 14) and an amplitude measurement unit (amplitude detector (diode) 16 and amplitude error detector 17).

In the present invention, the microwave microscope may be of a scanning type or a non-scanning type (in which complex dielectric constant at only predetermined position on sample 300 is measured) In this embodiment, the scanning type is employed.

The microwave resonator 100 has a long prismatic shape and is a strip line including a conductor line 101 located in the center when viewed in cross section, ground conductors (not illustrated in FIG. 1), and a dielectric layer 103. The microwave resonator 100 is of a both-end-opened type, and hence excitation and detection are separately performed at the first end 104 and the second end 105, respectively.

A probe (measurement unit) 120 is connected to a central portion of the conductor line 101 joining the first end 104 and the second end 105 of the microwave resonator 100 in a direction substantially perpendicular to an extending direction of the conductor line 111. The probe 120 protrudes to the outside of the microwave resonator 100 through a partially cut out portion 107 of the dielectric layer 103. In FIG. 1, the outline of the microwave resonator 100 is expressed by reference numeral 110. The probe 120 is a metal needle having a sharp tip end. The probe 120 is brought close to the sample 300 opposed thereto, and hence an amount associated with the complex dielectric constant of the sample may be measured.

To be more specific, the cut out portion 107 includes an exposed side wall of the dielectric layer 103y cut out in the direction perpendicular to the extending direction of the conductor line 101 of the microwave resonator and an exposed front wall of the dielectric layer 103x cut out in the extending direction of the conductor line 101 of the microwave resonator. The probe 120 protrudes from the dielectric layer 103x in a direction perpendicular to a surface of the dielectric layer 103x.

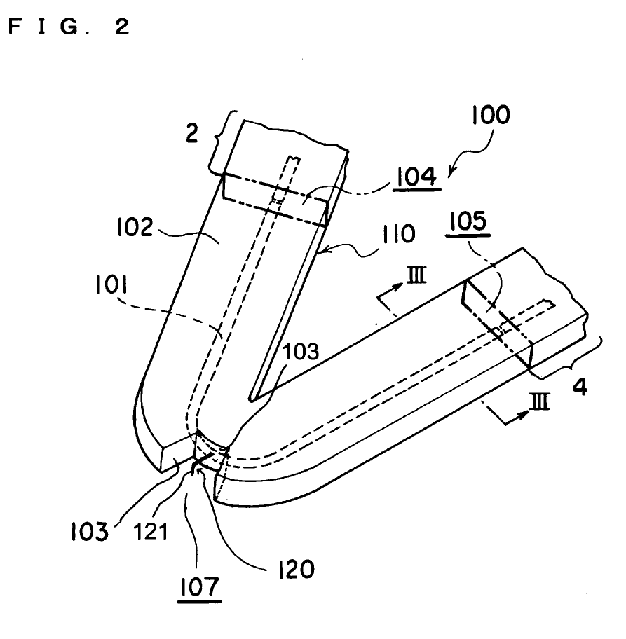

In the present invention, the “outside” of the microwave resonator means all surfaces included in an outer surface of the microwave resonator. When the cut out portion 107 is not provided, the “outside” means an outer surface of the strip line which is the microwave resonator. When the cut out portion 107 is provided, the “outside” means all surfaces of the microwave resonator, which include the surfaces of the cut out portion 107. Therefore, in a case illustrated in FIG. 2, the front wall (dielectric layer 103x) and the side wall (dielectric layer 103y) of the cut out portion 107 are also included in the “outside”.

The phrase “the probe (measurement unit) 120 protrudes to the outside of the microwave resonator” means that the measurement unit attached to any surface included in the outside of the microwave resonator is located without making contact with other surfaces included in the outside of the microwave resonator. For example, in the case illustrated in FIG. 2, when the cut out portion 107 is provided, the probe 120 attached to the front wall (dielectric layer 103x) is spaced from the side wall (dielectric layer 103y). Therefore, the probe 120 may be brought close to the sample 300 and a space for forming an optical path of a laser beam for an optical lever may be provided.

The amount associated with the complex dielectric constant of the sample is more specifically an amount calculated based on an amount associated with a resonant state of the microwave resonator 100 (change in complex resonant frequency). The change in complex resonant frequency is measured using the microwave microscope 1 as described later. The amount associated with the complex dielectric constant is for example, capacitance or conductivity of the sample.

In this embodiment, a surface 121 of the probe 120 is a mirror surface capable of reflecting a laser beam. The probe 120 may be slightly bent, and hence the probe 120 serves as a cantilever. The microwave microscope 1 further includes a laser light source 8a for irradiating the surface 121 of the probe 120 with a laser beam, a position detection sensor 8b for receiving a reflected beam of the irradiated laser beam, and a controller 8c. The laser light source 8a, the position detection sensor 8b, and the controller 8c correspond to a “distance control unit” in the present invention.

The microwave microscope 1 operates as follows.

When a microwave is generated from the oscillator (voltage controlled oscillator) 2, the phase shifter 12 receives an excitation signal of the microwave, adjusts a phase of the excitation signal, and outputs the adjusted excitation signal to the phase comparator 14. The generated microwave is supplied to the microwave resonator 100 through the capacitive coupling C1. The resonant state of the microwave resonator 100 is received by the detector 4 through the capacitive coupling C2.

The detector 4 receives the transmitted microwave and detects not only an amplitude of the microwave but also a complex amplitude of the microwave which includes the phase associated with the excitation signal. The following may be used as the detector 4. The excitation signal (for example, sin ωt), a component (cos ωt) different in phase from the excitation signal by 90 degrees, and the received transmission signal are mixed by a mixer (mathematically multiplied). Respective multiplied outputs (inphase and quadrature) are detected by diodes to obtain complex amplitudes. If necessary, the amplitude and the phase may be calculated based on the complex amplitudes.

The received signal is input to the phase comparator 14 and compared with the excitation signal from the phase shifter 12. The phase comparator 14 outputs (feeds back), to the oscillator 2, a phase difference between the excitation signal and the received signal as a phase difference signal (loop L1 in FIG. 1). The oscillator 2 controls oscillation so as to adjust the phase difference between the excitation signal and the received signal to a constant value, thereby tracking a resonant frequency. A system of feedback controlling the resonant frequency so as to adjust the phase difference between the output of the oscillator 2 and the received signal from the microwave resonator 100 to the constant value as described above is known as a so-called phase locked loop (PLL). Therefore, an oscillator output synchronized with an input signal is obtained.

The received signal is input to the amplitude detector 16 to detect an amplitude thereof. The detected amplitude is input to an amplitude error detector 17. The amplitude error detector 17 is a comparator and generates as an amplitude error signal a difference between the detected amplitude and a predetermined value “A”. The amplitude error signal from the amplitude error detector 17 is output (fed back) to the oscillator 2, and hence the oscillator 2 is controlled to obtain a constant excitation amplitude (loop L2 in FIG. 1).

The phase difference signal from the phase comparator 14 and the amplitude error signal from the amplitude error detector 17 are input to the overall control computer 10 and recorded as complex conjugate frequencies (resonant frequency and Q value), and imaged if necessary.

When the probe 120 provided in the microwave resonator 100 is brought close to the sample 300, the probe 120 interferes with the sample 300, thereby changing the effective resonator characteristics (resonant frequency and Q value) of the microwave resonator 100. In general, the resonant frequency is shifted to a low frequency side, the amplitude widens and the Q value reduces. The resonant frequency and the Q value change according to a capacitance or impedance of the sample 300. Therefore, the changes in resonant frequency and the Q value are detected to measure complex conjugate frequencies of the sample 300, and hence the amount associated with the complex dielectric constant may be obtained. For example, the complex conjugate frequencies of the sample 300 may be obtained with reference to a lookup table storing complex conjugate frequency data obtained by measuring a standard sample in advance.

When the oscillator 2 is provided with an automatic amplification factor control circuit, another method of detecting the change in Q value may be employed as follows. The received signal is detected and a difference between the received signal and a set value is amplified by an error amplifier. The amplified difference is used as a control signal of the automatic amplification control circuit. While the amplitude of the excitation signal may be maintained to a constant value, the control signal may be measured and recorded.

In this embodiment, the microwave microscope 1 is of the scanning type, and hence the sample is scanned as follows.

The sample 300 is set on a stage 7 provided on the piezoelectric actuator (position scanning unit) 6. The piezoelectric actuator 6 may be two-dimensionally shifted on an xy-plane (stage 7 surface) to relatively scan the sample 300 in x- and y-directions. As described later, the piezoelectric actuator 6 may be shifted in a z-direction (on plane perpendicular to surface of the stage 7), and hence a distance between the sample 300 and the probe 120 is maintained to a constant value. The operation of the piezoelectric actuator 6 is controlled by the controller (distance control unit) 8c.

The overall control computer 10 records the complex conjugate frequencies (resonant frequency and Q value) for each scanning data of the sample 300 which is obtained from the controller 8c, and maps (images) a complex dielectric characteristic (such as electrical impedance) for each coordinates of the sample 300 in each of the x- and y-directions. The overall control computer 10 causes a display (display unit) 11 to display image data as appropriate.

In this embodiment, the distance between the sample 300 and the probe 120 is controlled as follows.

When the distance between the sample 300 and the probe 120 changes and then the sample 300 is brought into contact with the probe 120, the probe 120 serving as the cantilever is bent to change a receiving position of a reflected beam on the position detection sensor 8b. The position detection sensor 8b is a four-part photo detector and uses an “optical lever” system to detect a displacement. In other words, a spot of a laser beam incident on the position detection sensor 8b is moved within the detector surface according to the displacement of the probe 120, and hence a difference on the four-part photo detector surfaces may be detected to detect the displacement of the probe 120.

A displacement signal from the position detection sensor 8b is input to the controller 8c. The controller 8c generates a control signal for canceling the displacement to operate the piezoelectric actuator 6 in the z-direction. When such feedback control is performed, the distance between the sample and the probe (which are located close to each other without making contact with each other) may be maintained to a constant value. Therefore, the measurement precision of the complex dielectric characteristic (such as electrical impedance) is improved.

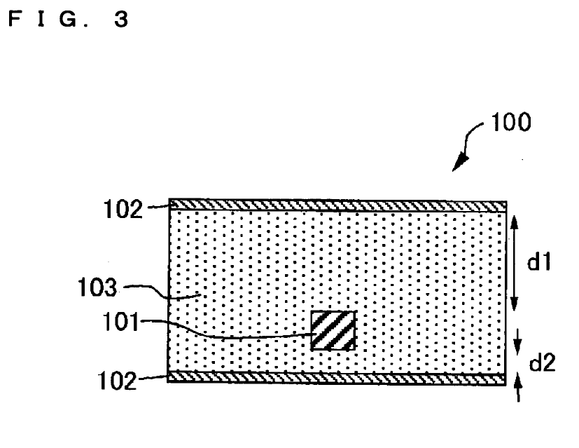

FIG. 2 illustrates a detailed structure of the microwave resonator 100. As illustrated in a cross sectional view of FIG. 3, the microwave resonator 100 is a long strip line having a rectangular cross-section. Ground conductors 102 are formed on upper and lower surfaces of the strip line. The dielectric layer 103 is interposed between the ground conductors 102. The conductor line 101 which is linear extends at a central portion of the dielectric layer 103 in a longitudinal direction of the strip line.

Returning to FIG. 2, the microwave resonator 100 is bent with a predetermined bending radius at a central portion in the longitudinal direction (joining first end 104 and second end 105). An outside protrusion portion of a bending portion of the strip line (including ground conductors 102 and dielectric layer 103) which is located outside the conductor line 101 is cut out to form the cut out portion 107.

The cut out portion is formed by cutting out from the side wall of the microwave resonator 100 to the vicinity of the conductor line 101. A portion of the dielectric layer 103 is slightly left in order to prevent the conductor line 101 from being exposed. The probe 120 is provided so as to be parallel to the ground conductors 102 and connected to the conductor line 101 through the portion of the dielectric layer 103 which is left in the side wall of the cut out portion. The probe 120 extending from the dielectric layer 103 to the outside is bent downward in the cut out portion 107 to tilt the tip end of the probe 120 downwardly. A frond surface of the probe 120 which is bent downwardly is a surface (mirror surface) 121.

Assume that an effective resonator length of a both-end opened resonator is expressed by LR. In this case, when a wavelength λ of an electromagnetic wave in the resonator satisfies λ=2LR/n (n is positive integer), resonance occurs. When n is an odd number, the central portion of the resonator is an electric field amplitude node. When n is an even number, the central portion of the resonator is an electric field amplitude loop.

Therefore, the measurement unit (probe and coil) 102 is provided in a position corresponding to the electric field amplitude loop or the electric field amplitude node at the central portion of the resonator. When n is the even number and the measurement unit is provided in the position corresponding to the electric field amplitude loop, the measurement unit is sensitive to electrical characteristics of the sample. On the other hand, when n is the odd number and the measurement unit is provided in the position corresponding to the electric field amplitude node (that is, magnetic field amplitude loop), the measurement unit is sensitive to magnetic characteristics of the sample. In the former case, when the measurement unit (probe) is a conductor having a sharp tip end, the electrical characteristics of the sample may be detected. In the latter case, when the coil is used as the measurement unit, the magnetic characteristics (including magnetic permeability) of the sample may be detected.

In the present invention, the “central portion” of the resonator may be the “central portion” with designed precision of approximately one several-tenth of a resonant wavelength.

In order to prevent the probe 120 from causing unnecessary resonance, a length of the probe 120 is desirably equal to or smaller than ¼ of the resonant wavelength, more desirably equal to or smaller than 1/10 of the resonant wavelength.

In the case of FIG. 2, the length of the probe 120 is a total length of the probe exposed to the outside (total of length of portion parallel to ground conductors 102 and length of downwardly bent portion).

The first end 104 and the second end 105 of the microwave resonator 100 are capacitively coupled to the oscillator 2 and the detector 4 (capacitive couplings C1 and C2). In this embodiment, the capacitive couplings C1 and C2 are formed by gaps provided between the first end 104 and the oscillator 2 and between the second end 105 and the detector 4.

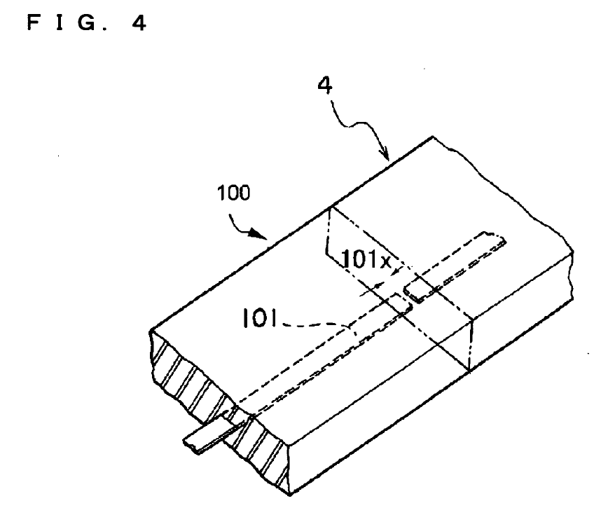

As illustrated in FIG. 4, one of the gaps is a gap 101x obtained in the longitudinal direction of the conductor line 101 at a position in which capacitive coupling is to be formed. The gap 101x may be filled with a dielectric. The gap for capacitive coupling desirably has a short interval of, for example, approximately 10 μm. The degrees of coupling of the two capacitive couplings C1 and C2 for determining a geometrical length of the microwave resonator 100 are not necessarily equal to each other and may be different from each other in view of excitation and detection conditions.

In this embodiment, a resonator length is 20 mm, a bending angle is 0.3 radians, and a bending radius is 1.5 mm. A length between the conductor line 101 and the tip end of the probe 120 is 1.5 mm.

In addition, in this embodiment, the strip line is longitudinally asymmetrical. In other words, in FIG. 3, a distance d1 between the upper ground conductor 102 and the conductor line 101 is longer than a distance d2 between the lower ground conductor 102 and the conductor line 101. To be specific, d1=0.9 mm and d2=0.13 mm. As described above, the length of the probe 120 is relatively short (for example, when resonant frequency is 20 GHz, ¼ of resonant wavelength is 1.5 mm). Therefore, when the strip line is made longitudinally asymmetrical and the probe 120 is made to protrude from the conductor line 101 to the lower ground conductor 102 side, the probe 120 protrudes from the lower ground conductor 102 to the outside, and hence the probe 120 is easily brought close to the sample and the distance between the probe 120 and the sample is easily measured (by, for example, optical lever system).

The present invention is not limited to the specific sizes.

As described above, according to the microwave resonator and the microwave microscope in the first embodiment of the present invention, both the ends of the microwave resonator are opened. Therefore, when the excitation unit and the detection unit are capacitively coupled to both the ends of the microwave resonator, the excitation unit for exciting the microwave resonator and the detection unit for detecting the microwave are separately provided at both the ends of the microwave resonator, and hence each end of the microwave resonator may be located at a sufficient distance so as not to interfere with each other.

In addition, the measurement unit is connected to the central portion of the conductor line joining both the ends of the microwave resonator and made to protrude to the outside of the microwave resonator, and hence the measurement unit itself is provided at a large distance from the excitation unit and the detection unit.

As a result, a degradation in S/N ratio due to leakage or interference of the excited wave to or with the received (detection) signal and a degradation in S/N ratio due to interference between the measurement unit and each of the excitation unit and the detection unit are suppressed. Therefore, the complex dielectric characteristic of the sample may be measured while a high S/N ratio is maintained.

In the present invention, a directional coupler which has a problem with band limitation or leakage is not used as the detection unit for the resonant state, and hence a signal may be detected in a wide band at high sensitivity.

In this embodiment, the distance control unit is provided to maintain the distance between the probe and the sample to a substantially constant value while the complex dielectric characteristic is measured. Therefore, reduction in measurement precision of the complex dielectric characteristic due to a change in distance between the probe and the sample may be suppressed.

### Second Embodiment

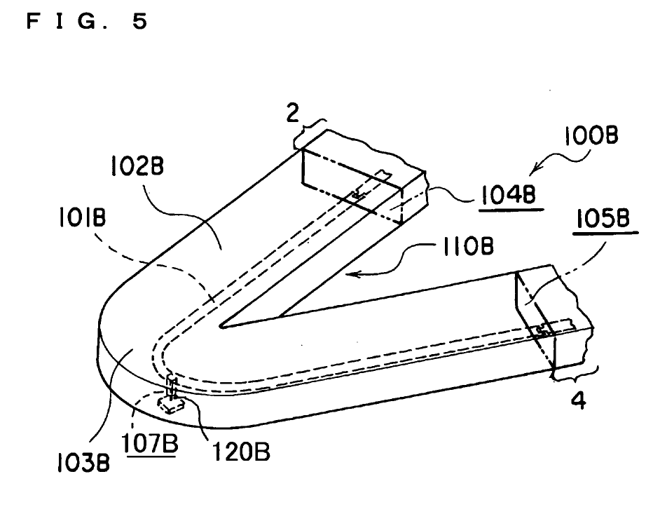

FIG. 5 illustrates a structure of a microwave resonator 100B according to a second embodiment of the present invention. A microwave microscope provided with the microwave resonator 100B has the same structure as the microwave microscope according to the first embodiment as illustrated in FIG. 1, and thus the description thereof is omitted.

As in the microwave resonator 100 according to the first embodiment, the microwave resonator 100B is a long strip line having a rectangular cross section. Ground conductors 102B are formed on upper and lower surfaces of the strip line. A dielectric layer 103B is interposed between the ground conductors 102B. A linear conductor line 101B extends at a central portion of the dielectric layer 103B in a longitudinal direction of the strip line.

The microwave resonator 100B is bent with a predetermined bending radius at a central portion thereof in the longitudinal direction. The strip line (including ground conductor 102B) is cut out in a lower portion of a bending portion thereof such that the conductor line 101 is exposed from an outer edge 110B of the microwave resonator, thereby forming a cut out portion (circular opening) 107B.

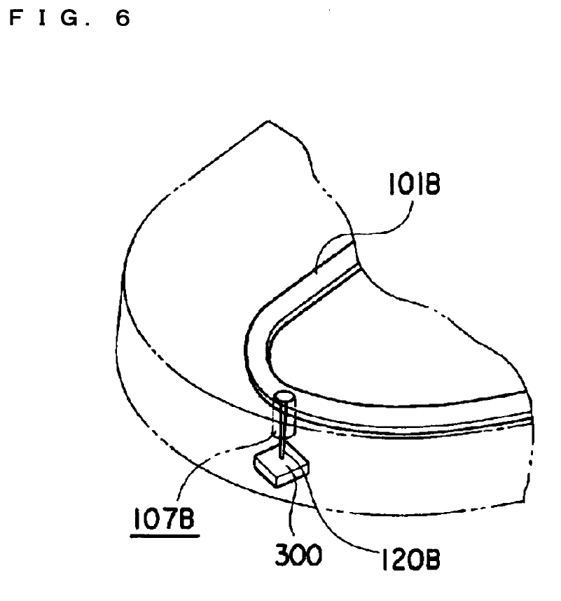

As illustrated in FIG. 6, a base end of a probe 120B is fixed to the conductor line 101B exposed from the cut out portion 107B and electrically connected to the conductor line 101B. A diameter of the cut out portion 107B is larger than a diameter of the probe 120B in order to prevent the probe 120B from making contact with the ground conductor 102B. The probe 120B is sharpened and made of metal (for example, platinum iridium).

As in the first embodiment, the probe 120B is provided in the position corresponding to the electric field amplitude node at the central portion of the microwave resonator 100B. In the second embodiment, the conductor line 101 is exposed from the cut out portion 107B, and hence it is likely to cause unnecessary resonance in the cut out portion 107B. Therefore, the diameter of the cut out portion 107B is set to a value equal to or smaller than ¼ of the resonant wavelength of the microwave resonator to prevent unnecessary resonance. The diameter of the cut out portion 107B is more desirably equal to or smaller than 1/10 of the resonant wavelength.

When the conductor line 101 is exposed from the cut out portion 107B as in the second embodiment, the “diameter” of the cut out portion 107B for preventing unnecessary resonance is a maximum length of an outer shape obtained by projecting an exposed portion of the cut out portion 107B to the outer edge 110B of the microwave resonator.

The opening portion of the cut out portion 107B may be filled with, for example a dielectric later to prevent unnecessary resonance.

The first end 104B and the second end 105B of the microwave resonator 100B are capacitively coupled to the oscillator 2 and the detector 4, respectively. In this embodiment, the capacitive couplings are formed by gaps provided between the first end 104B and the oscillator 2 and between the second end 105B and the detector 4.

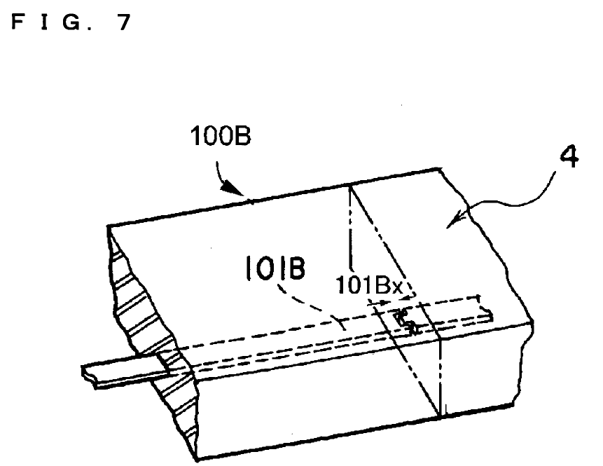

As illustrated in FIG. 7, one of the gaps is a gap 101Bx obtained in the longitudinal direction of the conductor line 101B at a position in which capacitive coupling is to be formed.

Two step portions are formed in a width direction of the conductor line 101B at an edge of the conductor line 101B which is in contact with the gap 101Bx. A central portion of the conductor line 101B which is sandwiched by the two step portions 101 protrudes forward in FIG. 7 to form the gap 101Bx as an interdigital gap whose edge portions are complicated.

When the degree of complication of the conductor line 101B in the width direction is adjusted, the degree of coupling may be controlled.

A dielectric layer is not necessarily provided in a space corresponding to the gap. Alternatively, a dielectric layer may be provided in the space. In the latter case, the dielectric layer of the microwave resonator 100B is desirably provided in the gap.

The gap desirably has a short interval of, for example, approximately 10 μm. The degrees of coupling of the two capacitive couplings are not necessarily equal to each other and may be different from each other in view of excitation and detection conditions.

### Third Embodiment

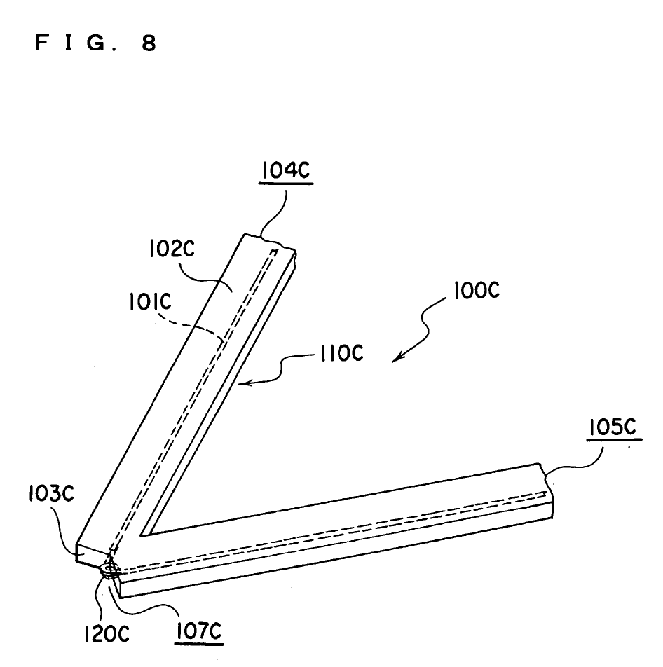

FIG. 8 illustrates a structure of a microwave resonator 100C according to a third embodiment of the present invention. A microwave microscope provided with the microwave resonator 100C has the same structure as the microwave microscope according to the first embodiment as illustrated in FIG. 1, and thus the description thereof is omitted.

As in the microwave resonator 100 according to the first embodiment, the microwave resonator 100C is a long strip line having a rectangular cross section. Ground conductors 102C are formed on upper and lower surfaces of the strip line. A dielectric layer 103C is interposed between the ground conductors 102C. A linear conductor line 101C extends at a central portion of the dielectric layer 103C in a longitudinal direction of the strip line.

The microwave resonator 100C is bent at a central portion thereof in the longitudinal direction. An outside portion of a bending portion of the strip line (including ground conductor 102C) which is located outside the conductor line 101C is cut out to form a cut out portion 107C. The cut out portion 107C has a shape obtained by cutting the outside portion of the bending portion which is located outside the conductor line 101C in a direction parallel to a width direction of the conductor line 101C. A cut end surface of the microwave resonator 100C is exposed in the bending portion.

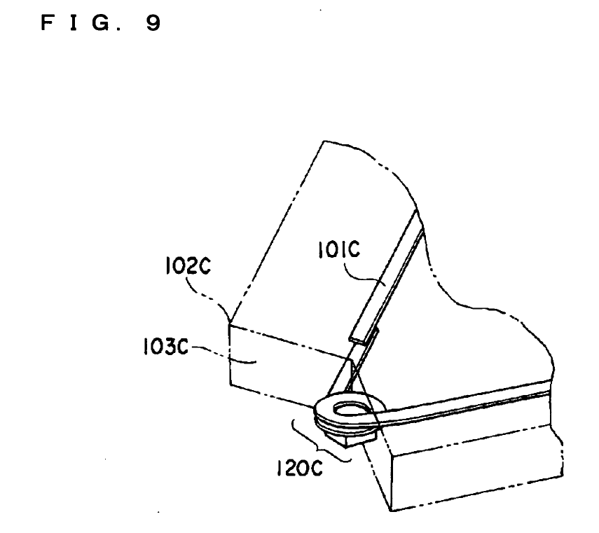

A portion of the conductor line 101C which is exposed from the cut out portion 107C is removed in order to provide a coil 120C illustrated in FIG. 9, thereby obtaining two conductor lines 101c.

As illustrated in FIG. 9, both ends of the coil (measurement unit) 120C of two turns are connected (in series) from the cut out portion 107C to the (two) conductor lines 101c through the dielectric layer 103C. Therefore, when the coil 120C is provided in a position corresponding to the electric field amplitude node (that is, magnetic field amplitude loop) at the central portion of the microwave resonator 100C, magnetic characteristics (including magnetic permeability) of the sample may be detected.

In the third embodiment, a geometrical conductor line length of the microwave resonator 100C is 28.55 mm (total length of extending portion of conductor line 101C between first and second ends 104C and 105C), a bending angle is 0.46 radians, a coil radius is 0.3 mm, and the number of turns is 1.36. The present invention is not limited to the specific values.

When a coil obtained by coating a carbon coil produced by, for example, focused ion beam (FIB) with a metal film is used to manufacture a finer coil, magnetic characteristics in a fine region may be detected.

The first end 104C and the second end 105C of the microwave resonator 100C are capacitively coupled to the oscillator 2 and the detector 4, respectively. The capacitive coupling is the same as in the first embodiment, and thus the description and illustration thereof are omitted.

In the third embodiment, the conductor lines 101C are not exposed from the cut out portion 107C, and hence the cut out portion 107C may be largely opened to expose the coil 120C.

### Fourth Embodiment

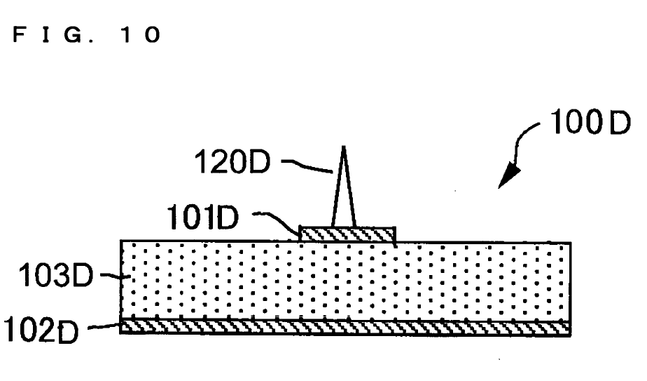

FIG. 10 is a cross sectional view illustrating a structure of a microwave resonator 100D according to a fourth embodiment of the present invention. Note that FIG. 10 is a cross sectional view taken along a plane perpendicular to an extending direction of a conductor line 101D. The other structure is the same as the microwave microscope illustrated in FIG. 1 according to the first embodiment, and thus the illustration thereof is omitted. As in the first embodiment, a probe 120D is provided at the center of the microwave resonator 100D.

The microwave resonator 110D according to the fourth embodiment is a micro-strip line. A dielectric layer 103D is formed on one surface of a ground conductor 102D. The conductor line 101D is provided on a center line of a surface of the dielectric layer 103D, thereby exposing the conductor line 101D to air.

The probe 120D extends from the conductor line 101D in an upward direction (direction perpendicular to surface of conductor line 101D). A base end of the probe 120D is electrically connected to the conductor line 101D.

In the fourth embodiment, manufacturing is easier. However, measurement precision slightly deteriorates because the conductor line 101D is exposed.

### Fifth Embodiment

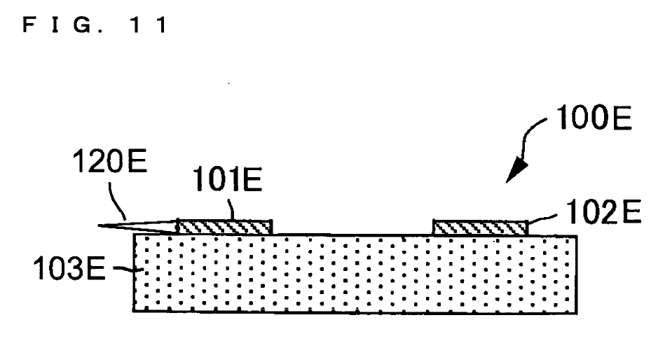

FIG. 11 is a cross sectional view illustrating a structure of a microwave resonator 100E according to a fifth embodiment of the present invention. Note that FIG. 11 is a cross sectional view taken along a plane perpendicular to an extending direction of a conductor line 101E. The other structure is the same as the microwave microscope illustrated in FIG. 1 according to the first embodiment, and thus the illustration thereof is omitted. As in the first embodiment, a probe 120E is provided at the center of the microwave resonator 100E.

The microwave resonator 100E according to the fifth embodiment is a coplanar line. A ground conductor 102E and a conductor line 101E are formed side by side on one surface of a dielectric layer 103E and are exposed to air.

The probe 120E extends laterally to the conductor line 101E (opposite to the ground conductor 102E) and in a direction parallel to a surface of the conductor line 101E. A base end of the probe 120E is electrically connected to the conductor line 101E.

Similarly in the fifth embodiment, manufacturing is easier. However, measurement precision slightly deteriorates because the conductor line 101E is exposed.

### Sixth Embodiment

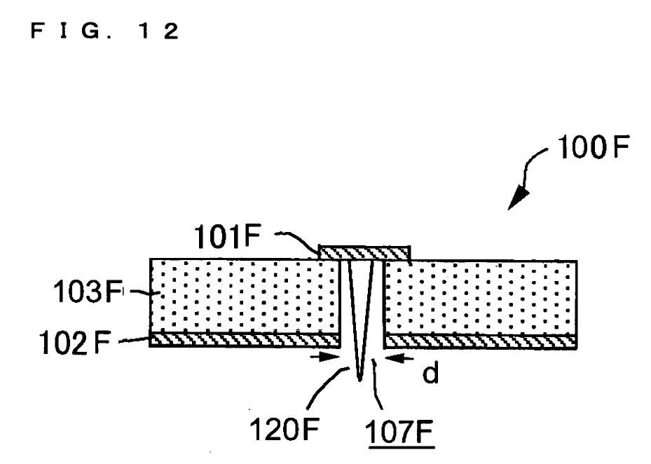

FIG. 12 is a cross sectional view illustrating a structure of a microwave resonator 101F according to a sixth embodiment of the present invention. FIG. 12 is identical to FIG. 10 except that a probe 120F is different in position from the probe 120D, and hence the same constituent portions as illustrated in FIG. 10 are expressed by the same reference symbols and the description thereof is omitted.

In the microwave resonator 101F according to the sixth embodiment, a cut out portion (opening) 101F is formed to extend from a conductor line 101F in a downward direction (direction which is perpendicular to surface of conductor line 101F and which extends toward ground conductor 102F) through a dielectric layer 103F. The probe 120F is provided in the cut out portion 107F. A base end of the probe 120F is electrically connected to the conductor line 11F. A tip end of the probe 120F protrudes from the ground conductor 102F to the outside while being spared a part from the ground conductor 102F.

In this case, when a diameter d of the cut out portion 107F is set to a value equal to or smaller than ¼ of the resonant wavelength (more desirably, value equal to or smaller than 1/10 of resonant wavelength), unnecessary resonance in the cut out portion 107F may be prevented to improve measurement precision.

The measurement precision in the sixth embodiment is higher than in the forth embodiment because the conductor line 101F is not exposed on the sample side (probe 120F side).

### Seventh Embodiment

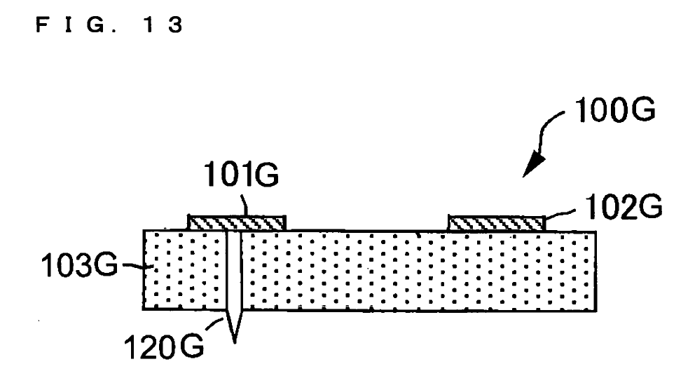

FIG. 13 is a cross sectional view illustrating a structure of a microwave resonator 100G according to a seventh embodiment of the present invention. FIG. 13 is identical to FIG. 11 except that a probe 120G is different in position from the probe 120E, and hence the same constituent portions as illustrated in FIG. 11 are expressed by the same reference symbols and the description thereof is omitted.

In the microwave resonator 100G according to the seventh embodiment, a probe 120G is provided to extend from a conductor line 101G in a downward direction (direction perpendicular to surface of conductor line 101F) through a dielectric layer 103G. A base end of the probe 120G is electrically connected to the conductor line 101G. A tip end of the probe 120G protrudes from the dielectric layer 103G to the outside.

In this case, the probe 120G is buried in the dielectric layer 103G, and thus no opening (cut out portion) is provided. Therefore, unnecessary resonance does not occur, and hence measurement precision may be improved.

The measurement precision in the seventh embodiment is higher than in the fifth embodiment because the conductor line 101G is not exposed on the sample side (probe 120G side).

The present invention is not limited to the embodiments described above, and encompasses various modifications and equivalents which are included in the idea and scope of the present invention.

For example, the microwave resonator may include, instead of the strip line, a coaxial cable, a micro-strip line, or a coplanar line.

The capacitive coupling may be formed by inserting an interdigital capacitor or a chip capacitor between at least one of the end portions of the microwave resonator and at least one of the excitation unit and the detection unit.

Instead of the optical lever, optical interference or a tuning fork may be used for the distance control unit. The tuning fork is a tuning fork type quartz vibrator for vibrating the measurement unit (probe). The measurement unit is provided at an end of the quartz vibrator. The quartz vibrator to which the measurement unit is attached is resonated by a piezoelectric element for excitation, to thereby vibrate the measurement unit. Only by reading charge information output from the quartz vibrator, the amplitude of the measurement unit may be simply detected, whereby the distance between the sample and the measurement unit may be controlled.

The probe may be a probe which is made of silicon by a semiconductor process and then provided with conductivity by forming a metal layer on a surface of the probe by evaporation. The probe and a cantilever may be integrally formed by a semiconductor process.

What is claimed is:

1. A microwave resonator of a both-end-opened type, comprising:
a conductor line;
a ground conductor; and
measurement means for measuring an amount associated with a complex dielectric constant of a sample while the measurement means is brought close to the sample,
wherein the measurement means is connected to the conductor line in a central portion joining a first end and a second end of the microwave resonator, and protrudes to an outside of the microwave resonator at a state estranged from the ground conductor.

2. A microwave resonator according to claim 1, wherein the microwave resonator comprises one of a coaxial cable, a micro-strip line, a strip line, and a coplanar line.

3. A microwave resonator according to claim 1, further comprising a dielectric layer,
wherein the conductor line is covered with the dielectric layer except the first end and the second end.

4. A microwave resonator according to claim 1, wherein the measurement means is provided in a cut out part of at least one of the ground conductor and the dielectric layer.

5. A microwave resonator according to claim 1, wherein the measurement means comprises one of a conductor having a sharp tip end and a coil.

6. A microwave resonator according to claim 5, wherein the coil comprises a coil frame containing carbon as a main component, and a conductive film coating a surface of the coil frame.

7. A microwave microscope, comprising:
the microwave resonator according to claim 1;
excitation means which is capacitively coupled to one of the first end and the second end of the microwave resonator, for exciting the microwave resonator; and
detection means which is capacitively coupled to another one of the first end and the second end of the microwave resonator, for detecting a microwave traveling from the another one of the first end and the second end.

8. A microwave microscope according to claim 7, further comprising distance control means for controlling a relative distance between the measurement means and the sample close to the measurement means.
